(19) United States
(12) Patent Application Publication
(10) Pub. No.: US 2023/0217584 A1
(43) Pub. Date: Jul. 6, 2023

(54) CIRCUIT BOARD, ANTENNA PACKAGE AND DISPLAY DEVICE

(71) Applicants: DONGWOO FINE-CHEM CO., LTD., Jeollabuk-do (KR); POSTECH RESEARCH AND BUSINESS DEVELOPMENT FOUNDATION, Gyeongsangbuk-do (KR)

(72) Inventors: Byung Jin CHOI, Incheon (KR); Na Yeon KIM, Seoul (KR); Dong Pil PARK, Incheon (KR); Won Bin HONG, Seoul (KR)

(21) Appl. No.: 18/122,829

(22) Filed: Mar. 17, 2023

Related U.S. Application Data
(63) Continuation of application No. PCT/KR2021/012509, filed on Sep. 14, 2021.

(30) Foreign Application Priority Data
Sep. 21, 2020 (KR) 10-2020-0121454

(51) Int. Cl. H05K 1/02; H01Q 1/24; H01Q 5/357

(52) U.S. Cl. CPC H05K 1/0253; H01Q 1/243; H01Q 5/357; H05K 1/0298

(57) ABSTRACT

A circuit board according to an embodiment includes a first substrate including an antenna feeder line formed thereon to connect an antenna driving unit and an antenna, a second substrate including a data line formed thereon to transmit data processed in the antenna driving unit to an electronic component, and a third substrate which is disposed between the first substrate and the second substrate, and includes a power supply line formed thereon to supply a power to the antenna driving unit.

### PRIORITY

The present application is a continuation application to International Application No. PCT/KR2021/012509 with an International Filing Date of Sep. 14, 2021, which claims the benefit of Korean Patent Application No. 10-2020-0121454 filed on Sep. 21, 2020 at the Korean Intellectual Property Office, the disclosures of which are incorporated by reference herein in their entirety.

### BACKGROUND

### 1. Technical Field

The present invention relates to a circuit board, an antenna package and a display device.

### 2. Background Art

Recently, according to development of the information-oriented society, wireless communication techniques such as Wi-Fi, Bluetooth, and the like are implemented, for example, in a form of smartphones by combining with display devices. In this case, an antenna may be coupled to the display device to perform a communication function.

Recently, with mobile communication techniques becoming more advanced, an antenna for performing communication in high frequency or ultra-high frequency bands corresponding to, for example, 3G to 5G is being coupled to the display device. In addition, according to development of thin, high-transparency and high-resolution display devices such as a transparent display and a flexible display, antennas are also being developed to have improved transparency and flexibility.

Meanwhile, such an antenna is connected to a circuit board on which an antenna driving circuit is mounted to be operated. Therefore, in order to improve performance of the antenna, it is necessary to develop a circuit board for the antenna.

### SUMMARY

It is an aspect of the present invention to provide a circuit board, an antenna package and a display device.

To achieve the above aspect, the following technical solutions are adopted in the present invention.

(1) A circuit board includes: a first substrate including an antenna feeder line formed thereon to connect an antenna driving unit and an antenna; a second substrate including a data line formed thereon to transmit data processed in the antenna driving unit to an electronic component; and a third substrate which is disposed between the first substrate and the second substrate, and includes a power supply line formed thereon to supply a power to the antenna driving unit.

(2) The circuit board according to the above (1), wherein the third substrate includes: a first power supply substrate including a first power supply line formed thereon to supply an analog power to the antenna driving unit; and a second power supply substrate including a second power supply line formed thereon to supply a digital power to the antenna driving unit.

(3) The circuit board according to the above (1), further including grounds disposed between the first substrate and the third substrate, and between the second substrate and the third substrate.

(4) The circuit board according to the above (1), further including a fourth board which is disposed between the second substrate and the third substrate, and includes another data line formed thereon to transmit the data processed in the antenna driving unit to another electronic component.

(5) The circuit board according to the above (4), further including grounds disposed between the second substrate and the fourth substrate, and between the fourth substrate and the third substrate.

(6) The circuit board according to the above (1), further including a fifth substrate which is formed between the first substrate and the third substrate, and includes another data line formed thereon to transmit the data processed in the antenna driving unit to another electronic component is formed.

(7) The circuit board according to the above (6), further including grounds disposed between the first substrate and the fifth substrate, and between the fifth substrate and the third substrate.

(8) The circuit board according to the above (1), wherein the first substrate includes: a first region in which the antenna driving unit is mounted; and a second region to which the antenna is connected.

(9) The circuit board according to the above (8), wherein the antenna feeder line is formed at the shortest distance between the first region and the second region to connect with each other.

(10) An antenna package includes: the circuit board according to the above-described embodiments; and an antenna element connected to an antenna feeder line of the circuit board.

(11) A display device includes the antenna package according to the above (10).

According to embodiments of the present invention, by forming the data lines, the power supply lines, and the antenna feeder lines on separate substrates and disposing the grounds between the respective substrates, it is possible to reduce signal interference and noise which may occur between the substrates or wirings formed on the substrates.

In addition, by forming the antenna feeder line on the circuit board to which the antenna is connected, it is possible to reduce a loss of electrical signals which may occur in the antenna feeder line when supplying a power to the antenna.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic cross-sectional view of a circuit board according to an embodiment;

FIG. 2 is a schematic plan view of a first substrate 110 shown in FIG. 1;

FIG. 3 is a schematic plan view of a second substrate 120 shown in FIG. 1;

FIG. 4 is a schematic cross-sectional view of a third substrate 130 shown in FIG. 1;

FIG. 5 is a schematic plan view of a first power supply substrate 410 shown in FIG. 4;

FIG. 6 is a schematic plan view of a second power supply substrate 420 shown in FIG. 4;

FIG. 7 is a schematic cross-sectional view of a circuit board according to another embodiment;

FIG. 8 is a schematic cross-sectional view of a circuit board according to another embodiment;

FIG. 9 is a schematic cross-sectional view illustrating an antenna package according to an embodiment;

FIG. 10 is a schematic plan view illustrating an antenna package according to an embodiment;

FIG. 11 is a schematic plan view illustrating an antenna package according to another embodiment; and

FIG. 12 is a schematic plan view illustrating a display device according to an embodiment.

### DETAILED DESCRIPTION OF THE EMBODIMENTS

Hereinafter, embodiments will be described in detail with reference to the accompanying drawings. In denoting reference numerals to components of respective drawings, it should be noted that the same components will be denoted by the same reference numerals although they are illustrated in different drawings.

In description of preferred embodiments of the present invention, the publicly known functions and configurations that are judged to be able to make the purport of the present invention unnecessarily obscure will not be described in detail. Further, wordings to be described below are defined in consideration of the functions of the embodiments, and may differ depending on the intentions of a user or an operator or custom. Accordingly, such wordings should be defined on the basis of the contents of the overall specification.

It will be understood that, although the terms first, second, etc. may be used herein to describe various elements or components, these elements or components should not be limited by these terms. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, components, electronic components, and/or a combination thereof, but do not preclude the presence or addition of one or more other features, integers, steps, operations, elements, components, electronic components and/or a combination thereof.

Further, directional terms such as “one side,” “the other side,” “upper,” “lower,” and the like are used in connection with the orientation of the disclosed drawings. Since the elements or components of the embodiments of the present invention may be located in various orientations, the directional terms are used for illustrative purposes, and are not intended to limit the present invention thereto.

In addition, a division of the configuration units in the present disclosure is intended for ease of description and divided only by the main function set for each configuration unit. That is, two or more of the configuration units to be described hereinafter may be combined into a single configuration unit or formed by two or more of divisions by function into more than a single configuration unit. Further, each of the configuration units to be described hereinafter may additionally perform a part or all the functions among functions set for other configuration units other than being responsible for the main function, and a part of the functions among the main functions set for each of the configuration units may be exclusively taken and certainly performed by other configuration units

The circuit board described herein may be a printed circuit board (PCB) on which an antenna driving unit (e.g., a radio frequency integrated circuit (RFIC), etc.) is mounted and used to drive the antenna together with the antenna driving unit. For example, the circuit board may be a Rigid PCB, a Flexible PCB (FCPB), or a Rigid-Flexible PCB (RF PCB).

In addition, the antenna may be a patch antenna or a microstrip antenna manufactured in a form of a transparent film. The circuit board, the antenna driving unit and the antenna may be applied to electronic devices for high frequency or ultra-high frequency (e.g., 3G, 4G, 5G or more) mobile communication, Wi-Fi, Bluetooth, near field communication (NFC), global positioning system (GPS), and the like, but it is not limited thereto. Herein, the electronic device may include a mobile phone, a smart phone, a tablet, a laptop computer, a personal digital assistant (PDA), a portable multimedia player (PMP), a navigation device, an MP3 player, a digital camera, a wearable device and the like. The wearable device may include a wristwatch type, a wrist band type, a ring type, a belt type, a necklace type, an ankle band type, a thigh band type, a forearm band type wearable device or the like. However, the electronic device is not limited to the above-described example, and the wearable device is also not limited to the above-described example.

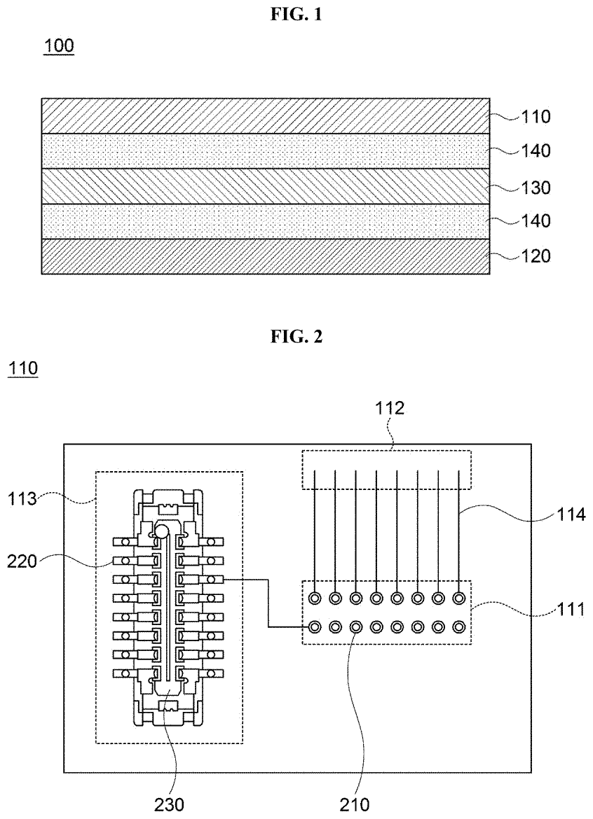

FIG. 1 is a schematic cross-sectional view of a circuit board according to an embodiment. FIG. 2 is a schematic plan view of a first substrate 110 shown in FIG. 1.

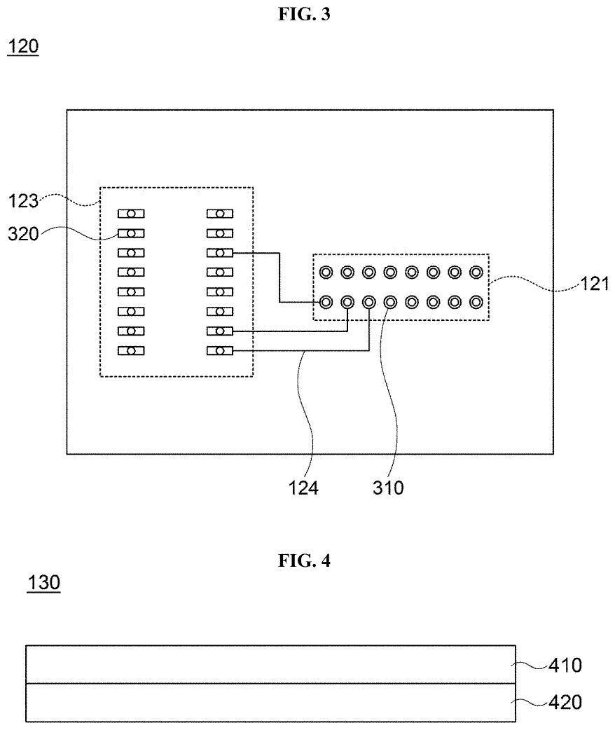

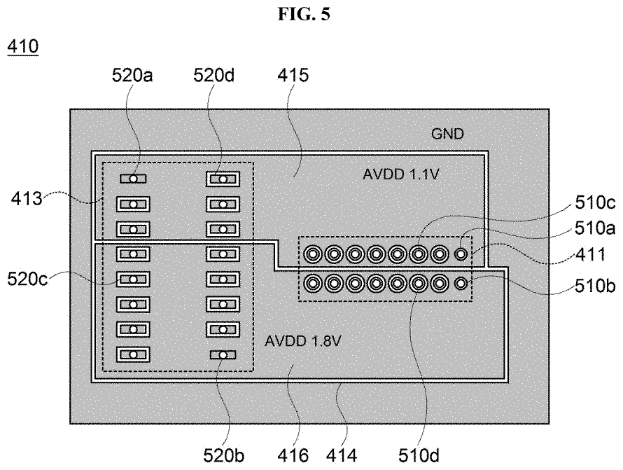

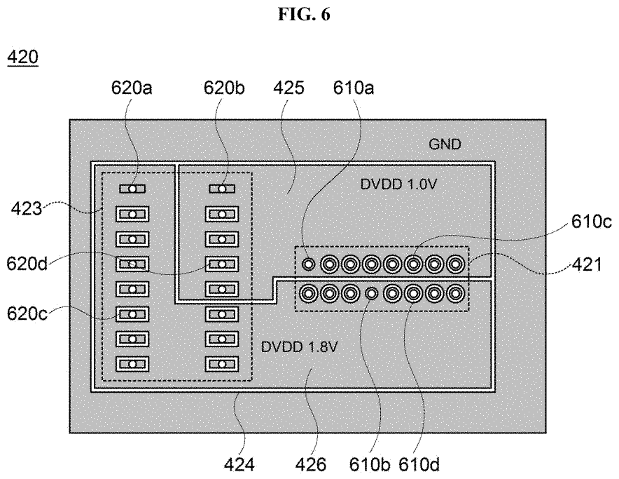

FIG. 3 is a schematic plan view of a second substrate 120 shown in FIG. 1. FIG. 4 is a schematic cross-sectional view of a third substrate 130 shown in FIG. 1. FIG. 5 is a schematic plan view of a first power supply substrate 410 shown in FIG. 4. FIG. 6 is a schematic plan view of a second power supply substrate 420 shown in FIG. 4.

Referring to FIGS. 1 to 6, a circuit board 100 according to an embodiment may include the first substrate 110, the second substrate 120, and the third substrate 130.

The first substrate 110 may be disposed at an upper portion of the circuit board 100.

The first substrate 110 may include a first region 111 in which an antenna driving unit may be mounted and a second region 112 in which an antenna may be mounted or connected.

First pads 210 on which the antenna driving unit is mounted may be formed in the first region 111. According to an embodiment, the first pad 210 may be a surface mount technology (SMT) pad to which the antenna driving unit is soldered, and each of the first pads 210 may have a conduction hole formed therein for connection between different layers. According to an embodiment, each lead of the antenna driving unit may be inserted into the conduction hole formed in each of the first pads 210.

The antenna or another circuit board on which the antenna is mounted may be bonded to the second region 112. Thereby, the antenna may be mounted or connected to the second region 112. For example, the antenna or another circuit board on which the antenna is mounted may be bonded to the second region 112 using an anisotropic conductive film (ACF) bonding technique, which is a bonding method that allows electrical conduction vertically, and insulates horizontally using an anisotropic conductive film (ACF), or using a connector (e.g., a coaxial cable connector or a board to board connector, etc.), but it is not limited thereto.

Antenna feeder lines 114 for connecting the first region 111 and the second region 112 may be formed on the first substrate 110. The antenna driving unit mounted in the first region 111 and the antenna mounted or connected to the second region 112 may be electrically connected with each other through the antenna feeder line 114. Herein, the antenna feeder line 114 may transmit a signal from the antenna driving unit mounted in the first region 111 to the antenna mounted or connected to the second region 112, and may transmit the signal from the antenna to the antenna driving unit.

The antenna mounted or connected to the second region 112 may include an array antenna. In this case, the number of antenna feeder lines 114 formed on a top surface of the first substrate 110 may be the same as the number of antenna elements forming the array antenna.

According to an embodiment, the antenna feeder line 114 may be formed by the shortest distance between the first region 111 and the second region 112 to connect with each other. By forming the antenna feeder line 114 by the shortest distance between the first region and the second region to connect with each other, a signal loss which may occur in the antenna feeder line 114 can be prevented.

According to an embodiment, the antenna feeder lines 114 may be formed to have substantially the same length as each other. Herein, the substantially same length may include not only the case where the lengths are exactly the same as each other, but also the case where the lengths are not exactly the same as each other due to problems in the process, but satisfy a predetermined condition. In this case, the predetermined condition may include a condition in which a gain deviation of the antenna connected to the antenna feeder lines 114 is dBi or less and/or a condition in which a phase delay difference of the antenna feeder lines 114 is below 10 degrees or less.

The antenna feeder lines 114 may be formed in a straight line as shown in FIG. 2. However, it is not limited thereto, and the antenna feeder lines 114 may be bent once or more.

The first substrate 110 may include a third region 113 in which a board to board (B to B) connector 230 is mounted.

Second pads 220 on which the B to B connector 230 is mounted may be formed in the third region 113. According to an embodiment, the second pad 220 may be a surface mount technology (SMT) pad to which the B to B connector 230 is soldered, and each of the second pads 220 may have a conduction hole formed therein for connection between different layers. According to an embodiment, each lead of the B to B connector 230 may be inserted into the conduction hole formed in each of the second pads 220.

The second substrate 120 may be disposed at a lower portion of the circuit board 100.

The second substrate 120 may include a fourth region 121 corresponding to the first region 111 of the first substrate 110 and a fifth region 123 corresponding to the third region 113 of the first substrate 110.

Third pads 310 may be formed in the fourth region 121. According to an embodiment, the third pad 310 may be a surface mount technology (SMT) pad, and each of the third pads 310 may have a conduction hole formed therein for connection between different layers. According to an embodiment, the lead of the antenna driving unit may be inserted into the conduction hole formed in each of the third pads 310.

Fourth pads 320 may be formed in the fifth region 123. According to an embodiment, the fourth pad 320 may be a surface mount technology (SMT) pad, and each of the fourth pads 320 may have a conduction hole formed therein for connection between different layers. According to an embodiment, the lead of the B to B connector 230 may be inserted into the conduction hole formed in each of the fourth pads 320.

In addition, data lines 124 which connect the fourth region 121 and the fifth region 123 may be formed on the second substrate 120. The antenna driving unit mounted in the first region 111 of the first substrate 110 and the electronic component mounted on the circuit board 100 may be electrically connected with each other through the data line 124. Herein, the data line may transmit data processed in the antenna driving unit to an electronic component, and transmit the data from the electronic component to the antenna driving unit. According to an embodiment, the electronic component may include various IC chips mounted on the circuit board 100 or another circuit board for an operation of an electronic device on which a resistor, a capacitor, an inductor, and the circuit board 100 are mounted.

Various electronic components including the above-described electronic component may be mounted on the first substrate 110 and/or the second substrate 120.

The third substrate 130 may be disposed between the first substrate 110 and the second substrate 120.

A power supply line for supplying a power to the antenna driving unit mounted on the first substrate 110 may be formed on the third substrate 130. According to an embodiment, as shown in FIG. 4, the third substrate 130 may include a first power supply substrate 410 and a second power supply substrate 420.

The first power supply substrate 410 may include a sixth region 411 corresponding to the first region 111 of the first substrate 110 and a seventh region 413 corresponding to the third region 113 of the first substrate 110.

Fifth pads 510a, 510b, 510c and 510d may be formed in the sixth region 411. According to an embodiment, the fifth pads 510a, 510b, 510c and 510d may be surface mount technology (SMT) pads, and each of the fifth pads 510a, 510b, 510c and 510d may have a conduction hole formed therein for connection between different layers. According to an embodiment, the lead of the antenna driving unit may be inserted into the conduction hole formed in each of the fifth pads 510a, 510b, 510c and 510d.

Sixth pads 520a, 520b, 520c and 520d may be formed in the seventh region 413. According to an embodiment, the sixth pads 520a, 520b, 520c and 520d may be surface mount technology (SMT) pads, and each of the sixth pads 520a, 520b, 520c and 520d may have a conduction hole formed therein for connection between different layers. According to an embodiment, the lead of the B to B connector 230 may be inserted into the conduction hole formed in each of the sixth pads 520a, 520b, 520c and 520d.

The first power supply substrate 410 may be divided into a first power supply region (e.g., an AVDD 1.1V region in FIG. 5), a second power supply region (e.g., an AVDD 1.8V region in FIG. 5) and a ground region through an isolation region 414. (e.g., a GND region of FIG. 5). A first power supply line 415 may be formed in the first power supply region, and a second power supply line 416 may be formed in the second power supply region. Herein, as shown in FIG. 5, the first power supply line 415 and the second power supply line 416 may be formed as a conductive electrode in order to prevent noise and increase efficiency of the power supply. Herein, the division between the first power supply region, the second power supply region, and the ground region may be variously altered according to designs.

At least one sixth pad 520a among a plurality of sixth pads belonging to the first power supply region and at least one fifth pad 510a among a plurality of fifth pads belonging to the first power supply region may be connected to the first power supply line 415. In this case, a first analog power supply (e.g., AVDD 1.1V) may be connected to the sixth pad 520a, thus to supply a first analog power to the antenna driving unit mounted on the first substrate 110 through the sixth pad 520a, the first power supply line 415 and the fifth pad 510a. Meanwhile, the remaining sixth pads 520d except for the sixth pad 520a among the plurality of sixth pads belonging to the first power supply region, and the remaining fifth pads 510c except for the fifth pad 510a among the plurality of fifth pads belonging to the first power supply region may be electrically separated from the first power supply line 415.

At least one sixth pad 520b among a plurality of sixth pads belonging to the second power supply region and at least one fifth pad 510b among a plurality of fifth pads belonging to the second power supply region may be connected to the second power supply line 416. In this case, a second analog power supply (e.g., AVDD 1.8V) may be connected to the sixth pad 520b, thus to supply a second analog power supply to the antenna driving unit mounted on the first substrate 110 through the sixth pad 520b, the second power supply line 416 and the fifth pad 510b. Meanwhile, the remaining sixth pads 520c except for the sixth pad 520b among the plurality of sixth pads belonging to the second power supply region, and the remaining fifth pads 510d except for the fifth pad 510b among the plurality of fifth pads belonging to the second power supply region may be electrically separated from the second power supply line 416.

Meanwhile, the fifth pads 510c and 510d and sixth pads 520c and 520d, which are not connected to the power supply lines 415 and 416, may be soldering pads for allowing the antenna driving unit or connector to be subjected to SMT. When performing SMT, leads may be formed on the fifth pads 510c and 510d, and the sixth pads 520c and 520d.

The second power supply substrate 420 may include an eighth region 421 corresponding to the first region 111 of the first substrate 110 and a ninth region 423 corresponding to the third region 113 of the first substrate 110.

Seventh pads 610a, 610b, 610c and 610d may be formed in the eighth region 421.

According to an embodiment, the seventh pads 610a, 610b, 610c and 610d may be surface mount technology (SMT) pads, and each of the seventh pads 610a, 610b, 610c and 610d may have a conduction hole formed therein for connection between different layers. According to an embodiment, the lead of the antenna driving unit may be inserted into the conduction hole formed in each of the seventh pads 610a, 610b, 610c and 610d.

Eighth pads 620a, 620b, 620c and 620d may be formed in the ninth region 423. According to an embodiment, the eighth pads 620a, 620b, 620c and 620d may be surface mount technology (SMT) pads, and each of the eighth pads 620a, 620b, 620c and 620d may have a conduction hole formed therein for connection between different layers. According to an embodiment, the lead of the B to B connector 230 may be inserted into the conduction hole formed in each of the eighth pads 620a, 620b, 620c and 620d.

The second power supply substrate 420 may be divided into a third power supply region (e.g., a DVDD 1.0V region in FIG. 6), a fourth power supply region (e.g., a DVDD 1.8V region in FIG. 6) and a ground region through an isolation region 424. (e.g., a GND region of FIG. 6). A third power supply line 425 may be formed in the third power supply region, and a fourth power supply line 426 may be formed in the fourth power supply region. Herein, as shown in FIG. 6, the third power supply line 425 and the fourth power supply line 426 may be formed as a conductive electrode in order to prevent noise and increase efficiency of the power supply. Herein, the division between the third power supply region, the fourth power supply region, and the ground region may be variously altered according to designs.

At least one eighth pad 620b among a plurality of eighth pads belonging to the third power supply region and at least one seventh pad 610a among a plurality of seventh pads belonging to the third power supply region may be connected to the third power supply line 425. In this case, a first digital power supply (e.g., DVDD 1.0V) may be connected to the eighth pad 620b, thus to supply a first digital power to the antenna driving unit mounted on the first substrate 110 through the eighth pad 620b, the third power supply line 425 and the seventh pad 610a. Meanwhile, the remaining eighth pads 620d except for the eighth pad 620b among the plurality of eighth pads belonging to the third power supply region, and the remaining seventh pads 610c except for the seventh pad 610a among the plurality of seventh pads belonging to the third power supply region may be electrically separated from the third power supply line 425.

At least one eighth pad 620a among the plurality of eighth pads belonging to the fourth power supply region and at least one seventh pad 610b among the plurality of seventh pads belonging to the fourth power supply region may be connected to the fourth power supply line 426. In this case, a second digital power supply (e.g., DVDD 1.8V) may be connected to the eighth pad 620a, thus to supply a second digital power to the antenna driving unit mounted on the first substrate 110 through the eighth pad 620a, the fourth power supply line 426 and the seventh pad 610b. Meanwhile, the remaining eighth pads 620c except for the eighth pad 620a among the plurality of eighth pads belonging to the fourth power supply region, and the remaining seventh pads 610d except for the seventh pad 610b among the plurality of seventh pads belonging to the fourth power supply region may be electrically separated from the fourth power supply line 426.

Meanwhile, seventh pads 610c and 610d and eighth pads 620c and 620d, which are not connected to the power supply lines 425 and 426, may be soldering pads for allowing the antenna driving unit or connector to be subjected to SMT. When performing SMT, leads may be formed on the seventh pads 610c and 610d, and the eighth pads 620c and 620d.

Meanwhile, according to an embodiment, the circuit board 100 may further include grounds 140 disposed between the first substrate 110 and the third substrate 130, and between the third substrate 130 and the second substrate 120. By forming the grounds 140 between the first substrate 110 and the third substrate 130, and between the third substrate 130 and the second substrate 120, signal interference and noise which may occur between the substrates can be removed.

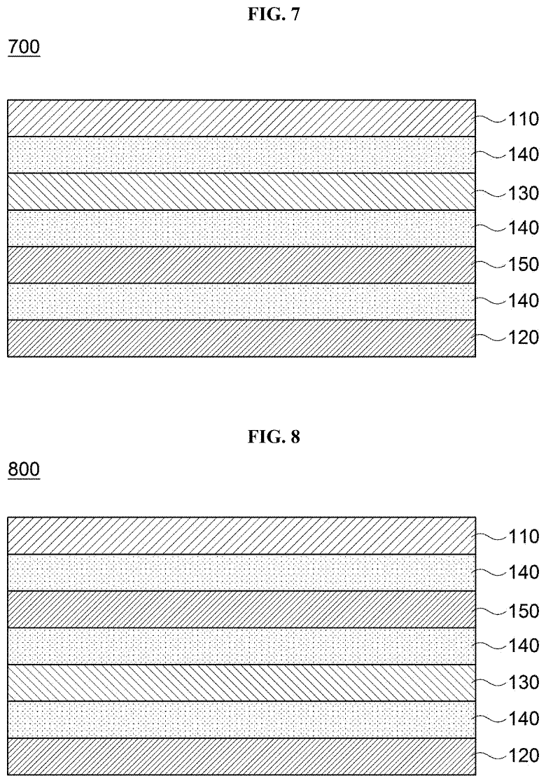

FIG. 7 is a schematic cross-sectional view of a circuit board according to another embodiment

Referring to FIG. 7, a circuit board 700 according to another embodiment may include a first substrate 110, a second substrate 120, a third substrate 130 and a fourth substrate 150. Herein, the first substrate 110, the second substrate 120, and the third substrate 130 are the same as those described with reference to FIGS. 1 to 6, therefore will not be described in detail.

The fourth substrate 150 may be disposed between the third substrate 130 and the second substrate 120.

The fourth substrate 150 may be formed in a structure similar to that of the second substrate 120 shown in FIG. 2. Similar to the second substrate 120, the fourth substrate 150 may include a data line which electrically connects the antenna driving unit mounted in the first region 111 of the first substrate 110 and an electronic component. The data line formed on the fourth substrate 150 may transmit data processed in the antenna driving unit to the electronic component and transmit the data from the electronic component to the antenna driving unit.

That is, in the circuit board 700 according to another embodiment, the data lines are formed dividedly into a plurality of substrates 120 and 150, thus to reduce a density of data lines formed on each substrate. Thereby, it is possible to remove signal interference and noise between data lines formed on the same substrate. In this case, the number and shape of the data lines formed on each of the substrates 120 and 150 may be determined in consideration of space utilization, the density of the data lines and the like.

Meanwhile, according to an embodiment, the circuit board 700 may further include grounds 140 disposed between the third substrate 130 and the fourth substrate 150, and between the fourth substrate 150 and the second substrate 120.

FIG. 8 is a schematic cross-sectional view of a circuit board according to another embodiment.

Referring to FIG. 8, unlike the circuit board 700 shown in FIG. 7, in a circuit board 800 according to another embodiment, a fourth substrate 150 may be disposed between a first substrate 110 and a third substrate 130. Meanwhile, the first substrate 110, the second substrate 120, the third substrate 130, the fourth substrate 150, and the ground 140 are substantially the same as those described with reference to FIGS. 1 to 7, therefore will not be described in detail.

FIGS. 7 and 8 illustrate an example in which one substrate 150 similar to the second substrate 120 is formed between the respective substrates, but it is not limited thereto. That is, a plurality of substrates similar to the second substrate 120 may be disposed between the respective substrates. In this case, by disposing grounds between the respective substrates, it is possible to remove signal interference and noise which may occur between the substrates.

Meanwhile, each of the substrates 110, 120, 130, 140, 150, 410 and 420 may include a prepreg.

According to an embodiment, by forming the data lines, the power supply lines, and the antenna feeder lines on separate substrates and disposing the grounds between the respective substrates, it is possible to reduce signal interference and noise which may occur between the substrates or wirings formed on the substrates. In addition, by forming the antenna feeder line on the circuit board to which the antenna is connected, it is possible to reduce a loss of electrical signals which may occur in the antenna feeder line when supplying a power to the antenna.

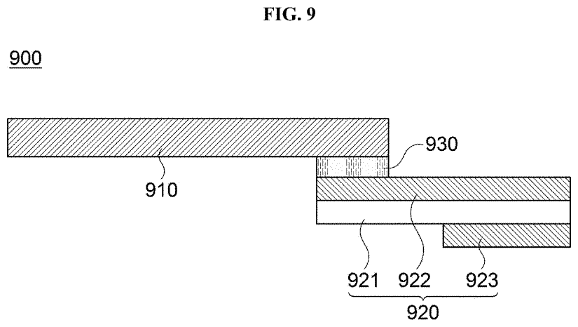

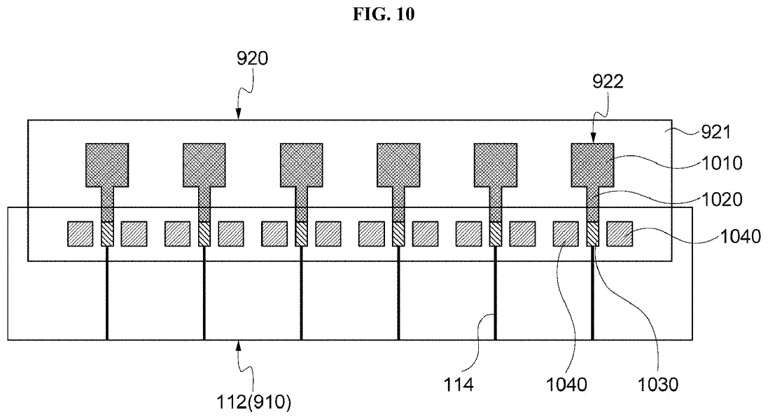

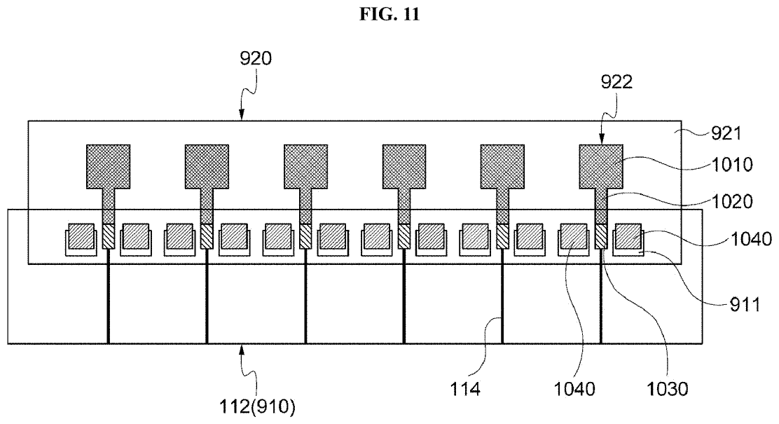

FIG. 9 is a schematic cross-sectional view illustrating an antenna package according to an embodiment, and FIG. 10 is a schematic plan view illustrating an antenna package according to an embodiment.

A circuit board 910 in FIGS. 9 and 10 may be the circuit boards 100, 700 and 800 described above with reference to FIGS. 1 to 8. For the convenience of description and illustration, FIG. 9 schematically shows the circuit board 910 as one layer or one substrate, and FIG. 10 shows the second region 112 of the circuit board 910, but does not show the first region 111 and the third region 113.

Referring to FIGS. 9 and10, an antenna package 900 according to an embodiment may include the circuit board 910 and an antenna element 920. Herein, the circuit board 910 is the same as the circuit boards 100, 700 and 800 described above with reference to shown in FIGS. 1 to 8, therefore will not be described in detail within the overlapping range.

The antenna element 920 may include an antenna dielectric layer 921 and an antenna unit 922.

The antenna dielectric layer 921 may include an insulation material having a predetermined dielectric constant. According to an embodiment, the antenna dielectric layer 921 may include an inorganic insulation material such as glass, silicon oxide, silicon nitride, or metal oxide, or an organic insulation material such as an epoxy resin, an acrylic resin, or an imide resin. The antenna dielectric layer 921 may function as a film substrate of the antenna element 920 on which the antenna unit 922 is formed.

According to an embodiment, the antenna dielectric layer 921 may include a polyester resin such as polyethylene terephthalate, polyethylene isophthalate, polyethylene naphthalate, polybutylene terephthalate, etc.; a cellulose resin such as diacetyl cellulose, triacetyl cellulose, etc.; a polycarbonate resin; an acrylic resin such as polymethyl (meth)acrylate, polyethyl (meth)acrylate, etc.; a styrene resin such as polystyrene, acrylonitrile-styrene copolymer, etc.; a polyolefin resin such as polyethylene, polypropylene, cyclic polyolefin or polyolefin having a norbornene structure, ethylene-propylene copolymer, etc.; a vinyl chloride resin; an amide resin such as nylon, aromatic polyamide; an imide resin; a polyether sulfonic resin; a sulfonic resin; a polyether ether ketone resin; a polyphenylene sulfide resin; a vinylalcohol resin; a vinylidene chloride resin; a vinylbutyral resin; an allylate resin; a polyoxymethylene resin; a thermoplastic resin such as an epoxy resin and the like. These compounds may be used alone or in combination of two or more thereof. In addition, a transparent film made of a thermosetting resin or an ultraviolet curable resin such as (meth)acrylate, urethane, acrylic urethane, epoxy, silicone, and the like may be used as the antenna dielectric layer 921.

According to an embodiment, the antenna dielectric layer 921 may include an adhesive film such as an optically clear adhesive (OCA), an optically clear resin (OCR) and the like.

According to an embodiment, the antenna dielectric layer 921 may be formed in a substantial single layer, or may be formed in a multilayer structure of two or more layers.

Capacitance or inductance may be generated by the antenna dielectric layer 921, thus to adjust a frequency band which can be driven or sensed by the antenna element 920. When the dielectric constant of the antenna dielectric layer 921 exceeds about 12, a driving frequency is excessively reduced, such that driving of the antenna in a desired high frequency band may not be implemented. Therefore, according to an embodiment, the dielectric constant of the antenna dielectric layer 921 may be adjusted in a range of about 1.5 to 12, and preferably about 2 to 12.

The antenna unit 922 may be formed on an upper surface of the antenna dielectric layer 921. For example, a plurality of antenna units 922 may be linearly or non-linearly arranged on the upper surface of the antenna dielectric layer 921 to form an array antenna.

The antenna unit 922 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Mn), cobalt (Co), nickel (Ni), zinc (Zn), tin (Sn), molybdenum (Mo), calcium (Ca), or an alloy including at least one thereof. These may be used alone or in combination of two or more thereof.

For example, the antenna unit 922 may include silver (Ag) or a silver alloy (e.g., a silver-palladium-copper (APC) alloy) to implement a low resistance. As another example, the antenna unit 922 may include copper (Cu) or a copper alloy (e.g., a copper-calcium (CuCa) alloy) in consideration of low resistance and fine line width patterning.

According to an embodiment, the antenna unit 922 may include a transparent conductive oxide such as indium tin oxide (ITO), indium zinc oxide (IZO), indium zinc tin oxide (IZTO), zinc oxide (ZnOx), or copper oxide (CuO).

According to an embodiment, the antenna unit 922 may include a lamination structure of a transparent conductive oxide layer and metal layer, for example, may have a two-layer structure of transparent conductive oxide layer-metal layer or a three-layer structure of transparent conductive oxide layer-metal layer-transparent conductive oxide. In this case, resistance may be reduced to improve signal transmission speed while improving flexible properties by the metal layer, and corrosion resistance and transparency may be improved by the transparent conductive oxide layer.

The antenna unit 922 may include a radiator 1010 and a transmission line 1020.

The radiator 1010 may be formed in a mesh structure. Thereby, transmittance of the radiator 1010 may be increased, and flexibility of the antenna element 920 may be improved. Therefore, the antenna element 920 may be effectively applied to a flexible display device.

A size of the radiator 1010 may be determined depending on a desired resonance frequency, radiation resistance, and gain. For example, the antenna unit 922 or the radiator 1010 may be implemented so as to transmit and receive signals in a resonance frequency band capable of performing high frequency or ultra-high frequency (e.g., 3G, 4G, 5G or more) mobile communication, Wi-Fi, Bluetooth, near field communication (NFC), global positioning system (GPS) and the like.

As shown in FIG. 1, the radiator 1010 may be implemented in a rectangular shape. However, this is only an example and there is no particular limitation on the shape of the radiator 1010. That is, the radiator 1010 may be implemented in various shapes such as a rhombus, circle and the like.

The transmission line 1020 may be formed by extending from the radiator 1010.

According to an embodiment, the transmission line 1020 may be formed as a substantial single member by integrally connecting with the radiator 1010, or may be formed as a separate member from the radiator 1010.

According to an embodiment, the transmission line 1020 may be formed in a mesh structure having substantially the same shape (e.g., having the same line width, the same interval, etc.) as the radiator 1010, but it is not limited thereto, and may be formed in a mesh structure having substantially different shape from the radiator 1010.

The antenna unit 922 may further include a signal pad 1030.

The signal pad 1030 may be connected to an end of the transmission line 1020, thus to be electrically connected to the radiator 1010 through the transmission line 1020.

According to an embodiment, the signal pad 1030 may be integrally connected with the transmission line 1020 to be formed as a substantially single member, or may be formed as a separate member from the transmission line 1020. For example, the signal pad 1030 may be formed as a member substantially integral with the transmission line 1020, and the end portion of the transmission line 1020 may be provided as the signal pad 1030.

According to an embodiment, a ground pad 1040 may be disposed around the signal pad 1030. For example, a pair of ground pads 1040 may be disposed to face each other with the signal pad 1030 interposed therebetween. The ground pads 1040 may be disposed around the signal pad 1030 so as to be electrically and physically separated from the signal pad 1030 and the transmission line 1020.

According to an embodiment, the signal pad 1030 and the ground pad 1040 may be formed in a solid structure made of the above-described metals or alloy in consideration of a reduction in power supply resistance and noise absorption efficiency.

Meanwhile, according to an embodiment, a dummy pattern (not illustrated) may be formed around the radiator 1010 and the transmission line 1020. The dummy pattern may include the same metal as that of the radiator 1010 and/or the transmission line 1020, and may be formed in a mesh structure having a shape which is the same as or different from the radiator 1010 and/or the transmission line 1020.

In addition, according to an embodiment, the antenna element 920 may further include an antenna ground layer 923 formed on a lower surface of the antenna dielectric layer 921. The antenna ground layer 923 may include the above-described metals or alloy. Since the antenna element 920 includes the antenna ground layer 923, vertical radiation characteristics may be implemented.

The antenna ground layer 923 may be at least partially overlapped with the antenna unit 922. For example, the antenna ground layer 923 may be entirely overlapped with the radiator 1010, but may not be overlapped with the transmission line 1020, the signal pad 1030 and the ground pad 1040. As another example, the antenna ground layer 923 may be entirely overlapped with the radiator 1010 and the transmission line 1020, but may not be overlapped with the signal pad 1030 and the ground pad 1040. As another example, the antenna ground layer 923 may be entirely overlapped with the radiator 1010, the transmission line 1020, the signal pad 1030 and the ground pad 1040.

According to an embodiment, a conductive member of the display device or a display panel on which the antenna package 900 is mounted may be provided as the antenna ground layer 923. For example, the conductive member may include electrodes or wirings such as a gate electrode, source/drain electrodes, pixel electrode, common electrode, data line, scan line, etc. of a thin film transistor (TFT) included in the display panel, and a stainless steel (SUS) plate, heat radiation sheet, digitizer, electromagnetic shielding layer, pressure sensor, fingerprint sensor, etc. of the display device.

The antenna element 920 may be connected to the second region 112 of the circuit board 910. For example, pads 1030 and 1040 of the antenna element 920 may be bonded to the second region 112, such that the antenna unit 922 may be connected to the antenna feeder line 114. In addition, as described above with reference to FIG. 1, the antenna driving unit may be mounted in the first region 111 (see FIG. 1), and the antenna driving unit may be connected to the antenna feeder line 114. Thereby, a power and a driving signal may be applied to the antenna unit 922 via the antenna feeder line 114 by the antenna driving unit.

The circuit board 910 may include a coverlay film to cover the antenna feeder lines 114. In this case, by cutting or removing a portion of the coverlay film of the circuit board 910, one end of each of the antenna feeder lines 114 may be exposed, and the exposed one end of each of the antenna feeder lines 114 may be adhered to the signal pad 1030. More specifically, a conductive relay structure 930 such as an anisotropic conductive film (ACF) to the signal pads 1030 and the ground pads 1040, and then the second region 112 of the circuit board 910, in which the exposed one end of each of the antenna feeder lines 114 is positioned, may be disposed on the conductive relay structure 930. Thereafter, the second region 112 of the circuit board 910 may be attached to the antenna element 920 through a heat treatment/pressing process, and each of the antenna feeder lines 114 may be electrically connected to each signal pad 1030. In addition, as the ground pads 1040 are arranged around the signal pad 1030, adhesion with the anisotropic conductive film (ACF) may be increased, and bonding stability may be improved.

The antenna feeder lines 114 may be individually and independently connected to each antenna unit 922. Thereby, power supply/driving control may be independently performed for each of the antenna units 922. For example, different phase signals may be applied to each antenna unit 922 through the antenna feeder line 114 connected to each of the antenna units 922.

FIG. 11 is a schematic plan view illustrating an antenna package according to another embodiment. For the convenience of description and illustration, FIG. 11 shows the second region 112 of the circuit board 910, but does not show the first region 111 and the third region 113.

Referring to FIG. 11, the circuit board 910 may include a bonding pad 911.

The bonding pad 911 may be disposed around the antenna feeder line 114. For example, a pair of bonding pads 911 may be disposed with one antenna feeder line 114 interposed therebetween.

The bonding pad 911 is electrically and physically separated from the antenna feeder line 114, and may be bonded to the ground pad 1040 of the antenna element 920 through the conductive relay structure 930 (see FIG. 9). Bonding stability between the antenna element 920 and the circuit board 910 may be further improved through the bonding pads 911.

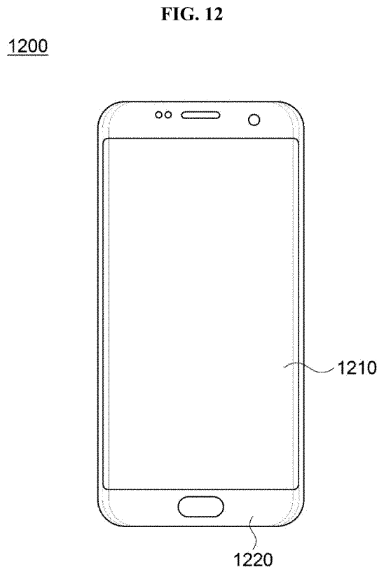

FIG. 12 is a schematic plan view illustrating a display device according to an embodiment. More specifically, FIG. 12 is a view illustrating a front portion or a window surface of the display device.

Referring to FIG. 12, a display device 1200 may include a display region 1210 and a peripheral region 1220 which are formed on the front portion thereof The display region 1210 may indicate a region in which visual information is displayed, and the peripheral region 1220 may an opaque region disposed on both sides and/or both ends of the display region 1210. For example, the peripheral region 1220 may correspond to a light-shielding part or a bezel part of the display device 1200.

The above-described antenna element 920 may be disposed toward the front portion of the display device 1200, for example, may be disposed on the display panel. In an embodiment, the radiator 1010 and/or the transmission line 1020 may be at least partially overlapped with the display region 1210.

In this case, the radiator 1010 and/or the transmission line 1020 may be formed in a mesh structure, and a decrease in transmittance due to the radiator 1010 and/or the transmission line 1020 may be prevented.

The circuit board 910 may be disposed in the peripheral region 1220 to prevent a deterioration of image quality in the display region 1210.

The present invention has been described with reference to the preferred embodiments above, and it will be understood by those skilled in the art that various modifications may be made within the scope without departing from essential characteristics of the present invention. Accordingly, it should be interpreted that the scope of the present invention is not limited to the above-described embodiments, and other various embodiments within the scope equivalent to those described in the claims are included within the present invention.

What is claimed is:

1. A circuit board, comprising:
a first substrate comprising an antenna feeder line formed thereon to connect an antenna driving unit and an antenna;
a second substrate comprising a data line formed thereon to transmit a data processed in the antenna driving unit to an electronic component; and
a third substrate which is disposed between the first substrate and the second substrate, and comprises a power supply line formed thereon to supply a power to the antenna driving unit.

2. The circuit board according to claim 1, wherein the third substrate comprises:
a first power supply substrate comprising a first power supply line formed thereon to supply an analog power to the antenna driving unit; and
a second power supply substrate comprising a second power supply line formed thereon to supply a digital power to the antenna driving unit.

3. The circuit board according to claim 1, further comprising grounds disposed between the first substrate and the third substrate, and between the second substrate and the third substrate.

4. The circuit board according to claim 1, further comprising a fourth board which is disposed between the second substrate and the third substrate, and comprises another data line formed thereon to transmit the data processed in the antenna driving unit to another electronic component.

5. The circuit board according to claim 4, further comprising grounds disposed between the second substrate and the fourth substrate, and between the fourth substrate and the third substrate.

6. The circuit board according to claim 1, further comprising a fifth substrate which is formed between the first substrate and the third substrate, and comprises another data line formed thereon to transmit the data processed in the antenna driving unit to another electronic component is formed.

7. The circuit board according to claim 6, further comprising grounds disposed between the first substrate and the fifth substrate, and between the fifth substrate and the third substrate.

8. The circuit board according to claim 1, wherein the first substrate comprises:
a first region in which the antenna driving unit is mounted; and
a second region to which the antenna is connected.

9. The circuit board according to claim 8, wherein the antenna feeder line is formed by the shortest distance between the first region and the second region to connect with each other.

10. An antenna package comprising:
the circuit board according to claim 1; and
an antenna element connected to the antenna feeder line of the circuit board.

11. A display device comprising the antenna package according to claim 10.
